(19) United States
(12) Patent Application Publication
(10) Pub. No.: US 2014/0061712 A1
(43) Pub. Date: Mar. 6, 2014

(54) SIDE VIEW LIGHT EMITTING DIODE PACKAGE AND METHOD FOR MANUFACTURING THE SAME

(71) Applicant: ADVANCED OPTOELECTRONIC TECHNOLOGY, INC., Hsinchu Hsien 303 (TW)

(72) Inventors: HOU-TE LIN, Hsinchu (TW); CHAO-HSIUNG CHANG, Hsinchu (TW); PIN-CHUAN CHEN, Hsinchu (TW); LUNG-HSIN CHEN, Hsinchu (TW); WEN-LIANG TSENG, Hsinchu (TW)

(73) Assignee: ADVANCED OPTOELECTRONIC TECHNOLOGY, INC., Hsinchu Hsien 303 (TW)

(21) Appl. No.: 13/971,858

(22) Filed: Aug. 21, 2013

(30) Foreign Application Priority Data
Aug. 31, 2012 (CN) 2012103173874

(51) Int. Cl. H01L 33/38

(52) U.S. Cl. CPC H01L 33/387
USPC 257/99; 438/27

(57) ABSTRACT

A side view light emitting diode (LED) package includes an electrode structure, an LED die disposed on the electrode structure and an encapsulation layer covering the LED die. The encapsulation layer includes a light outputting surface. The electrode structure includes a first electrode and a second electrode spaced from each other to define a tortuous gap therebetween. Resin material for forming a substrate of the LED package fills in the gap to interconnect the first and second electrode together. The LED die is electrically connected to the first electrode and the second electrode. The present disclosure also provides a method for manufacturing the side view LED package.

### BACKGROUND

1. Technical Field

The present disclosure generally relates to semiconductor structures and methods for manufacturing the same, and particularly to a side view light emitting diode (LED) and a method for manufacturing the same.

2. Description of the Related Art

LEDs are solid state light emitting sources, which are more stable and reliable than other conventional light sources such as incandescent bulbs. Thus, LEDs are being widely used in various fields such as numeral/character displaying elements, signal lights, light sources for lighting and display devices.

A traditional side view LED package includes an electrode structure and an LED die electrically contacting with the electrode structure. The electrode structure includes a first electrode and a second electrode. The first electrode and the second electrode are generally rectangular parallelepiped shaped and spaced from each other to form a gap therebetween. Resin material for forming a substrate of the LED package fills in the gap. When the side view LED package is mounted on the printed circuit board by surface-mount technology (SMT), a thermal stress is applied to the electrode structure of the side view LED package, which induces a reactive stress in the part of the substrate at the gap. Due to that the resin for forming the substrate has a strength less than that of the metal for forming the electrode structure, the reactive stress can possibly cause the part of the substrate at the gap to be broken whereby the LED package is so damaged that it can no longer be normally used.

Therefore, it is desirable to provide a side view LED package which can overcome the above-described problems.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present side view LED package. Moreover, in the drawings, all the views are schematic, and like reference numerals designate corresponding parts throughout the views.

FIG. 1 is a front view of a side view LED package in accordance with a first embodiment of the present disclosure.

FIG. 2 is a rear view of the side view LED package of FIG. 1.

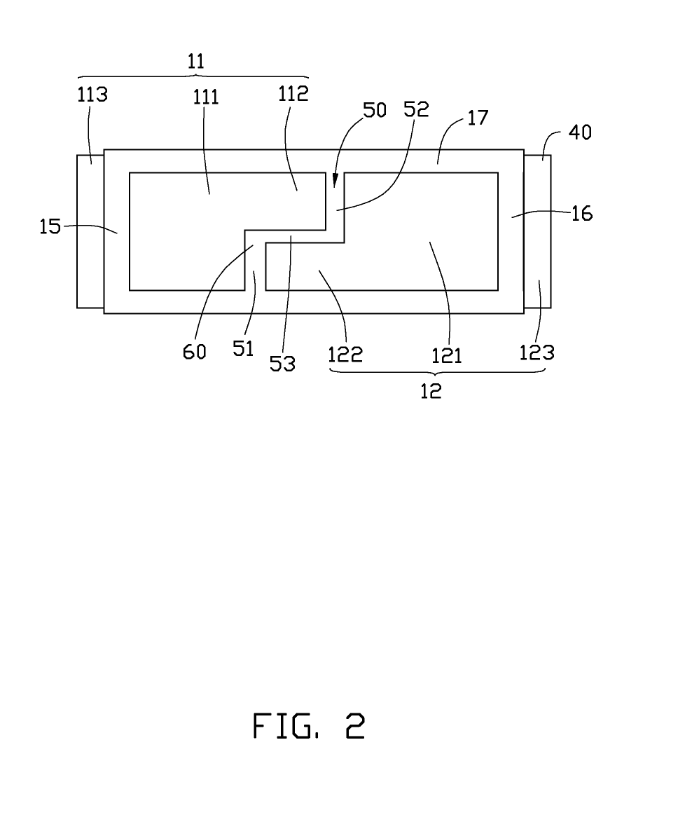

FIG. 3 is a cross-sectional view of the side view LED package of FIG. 1 taken along line III-III thereof.

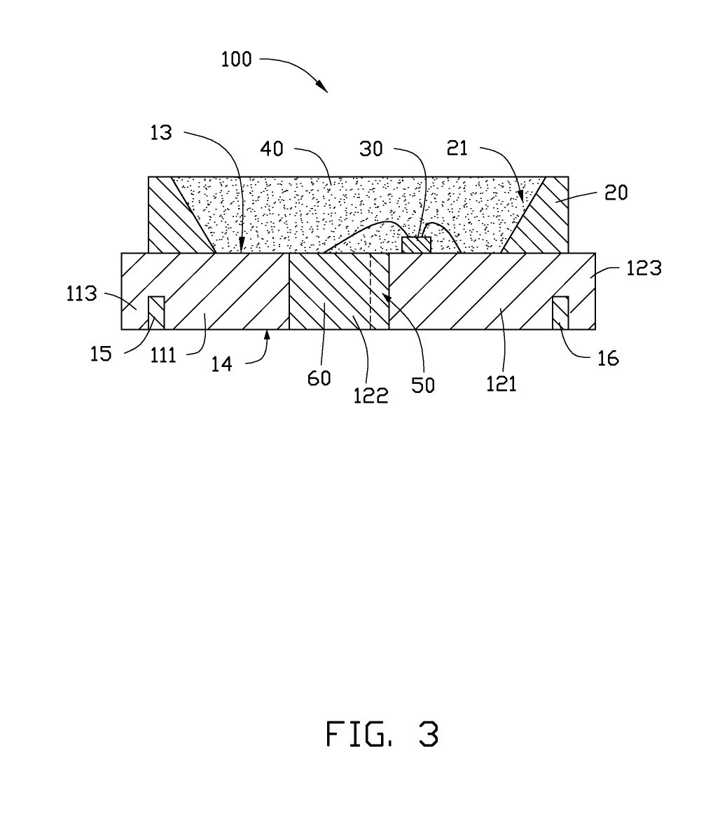

FIG. 4 is a front view of a side view LED package in accordance with a second embodiment of the present disclosure.

FIG. 5 is a rear view of the side view LED package of FIG. 4.

FIG. 6 is a cross-sectional view of the side view LED package of FIG. 4 taken along line VI-VI thereof.

### DETAILED DESCRIPTION

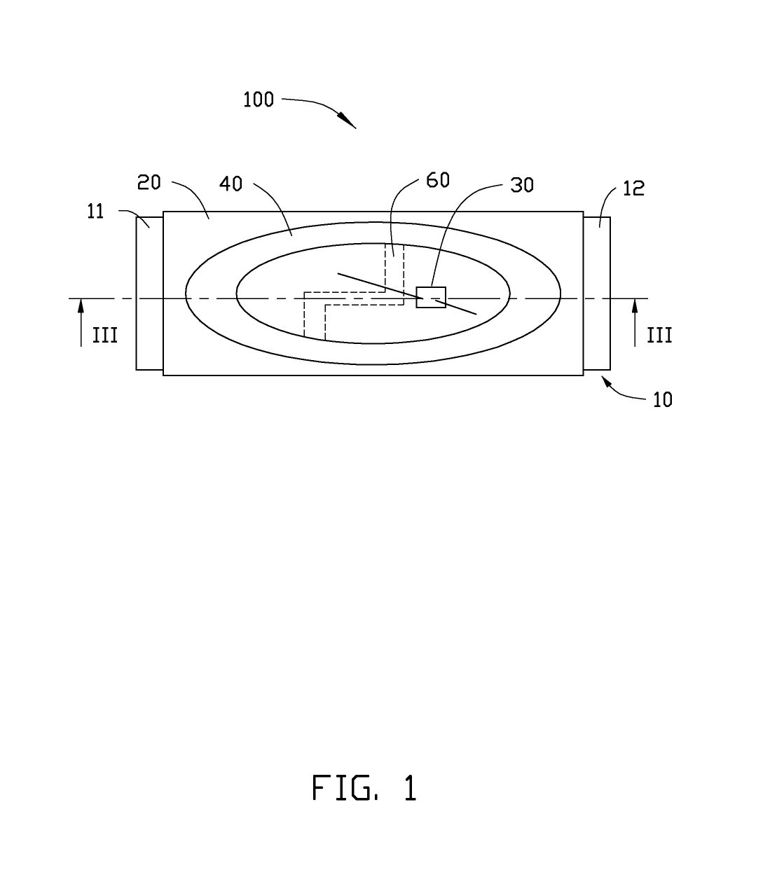

Referring to FIG. 1, a side view LED package 100 in accordance with a first exemplary embodiment is provided. The side view LED package 100 includes an electrode structure 10, a reflector 20 and an LED die 30 disposed on the electrode structure 10, and an encapsulation layer 40 encapsulating the LED die 30.

Specifically, the electrode structure 10 includes a first electrode 11 and a second electrode 12. The first electrode 11 and the second electrode 12 are spaced from each other to form a gap 50 therebetween. Insulation material for forming a substrate 60 of the LED package 100 is also filled in the gap 50. Each of the electrodes 11, 12 includes a first surface 13 and a second surface 14.

The first electrode 11 includes a first main body 111, a first extending portion 112 extending toward the second electrode 12 from one side of the first main body 111 along a width direction of the first main body 111, and a first soldering bump 113 extending to a left side of the substrate 60 from the first main body 111. A first groove 15 is defined in the second surface 14 of the first main body 111, and the first groove 15 is located at a left side of the first main body 111 adjacent to the first soldering bump 113. The first extending portion 112 is a rectangle. The extending portion 112 extends horizontally from an upper, right corner of the first main body 111, whereby the extending portion 112 and the first main body 111 cooperatively form an L-shaped configuration. A height of the first soldering bump 113 is larger that of the first main body 111 for mounting the side view LED package 100 to a printed circuit board (PCB) (not shown) by SMT (surface-mount technology).

The second electrode 12 includes a second main body 121 being symmetrical to the first main body 111, a second extending portion 122 extending horizontally toward the first electrode 11 from a lower, left corner of the second main body 121 along a width direction of the second main body 121, and a second soldering bump 123 extending to a right side of the substrate 60 from the second main body 121. A second groove 16 is defined in the second surface 14 of the second main body 121, and the groove 16 is located at a right side of the second main body 121 adjacent to the second soldering bump 123. A shape of the second groove 16 is the same as that of the first groove 15. The first groove 15, the second groove 16, and peripheries of the second surfaces 14 of the two electrodes 11, 12 are filled with resin materials to form a resin layer 17. The resin layer 17 combines the two electrodes 11, 12 together. A distance between a bottom surface of each of the soldering bumps 113, 123 and a bottom surface of the substrate of 10 the LED package 100 is smaller than 100 micrometers (mm). The second extending portion 122 and the second main body 121 cooperatively form an L-shaped configuration which is complementary to the L-shaped configuration formed by the first extending portion 112 and the first body portion 111. A size of the second soldering bump 123 is the same as that of the first soldering bump 113. The first soldering bump 113 and the second soldering bump 123 are symmetrically arranged.

The first electrode 11 and the second electrode 12 are arranged in an interlocked manner along a horizontal direction. Specifically, the gap 50 includes a first extending section 51, a second extending section 52, and a middle section 53 interconnecting the first extending section 51 and the second extending section 52, wherein the first extending section 51 is perpendicular to the middle extending section 53 which in turn is perpendicular to the second extending section 52. Specifically, the first main body 111 and a free end of the second extending portion 122 are spaced to form the first extending section 51. The second main body 121 and a free end of the first extending portion 112 are spaced to form the second extending section 52. The first extending portion 112 and the second extending portion 122 are spaced from each other to have the middle section 53 therebetween. End surfaces of the first electrode 11 and the second electrode 12 are correspondingly paralleled from each other. In this embodiment, the middle section 53 is horizontal and perpendicular to the first extending section 51 and the second extending section 52. Alternatively, the middle section 53 and the first extending section 51 are not parallel, and/or the middle section 53 and the second extending section 52 are not parallel.

The reflector 20 is formed on the first surfaces 13 of the first main body 111 and the second main body 121, wherein a lateral periphery of the reflector 20 is coplanar with the side surfaces of the two main bodies 111, 121 adjacent to the soldering bumps 113, 123 for exposing the two soldering bumps 113, 123. A high reflective material may be arranged at an inner surface of the reflector 20. The reflector 20, the electrode structure 10 and the substrate 60 are engaged together to form a recess 21, wherein a demission of the top end of the recess 21 is greater than that of the bottom end of the recess 21. The resin layer 17 and the reflector 20 are an integral part of the substrate 60.

The LED die 30 is arranged on the second electrode 12 and located on the second main body 121 of the second electrode 12. The LED die 30 electrically connects with the first extending portion 112 of the first electrode 11 and the second main body 121 of the second electrode 12 by wire bonding. Alternatively, the LED die 30 could also be arranged on the second extending portion 122 and electrically connects with the second extending portion 122 and the first main body 111 by wire bonding. Correspondingly, a length of the bonding wire is reduced and a manufacturing cost is decreased.

The encapsulation layer 40 is arranged above the LED die 30 and filled in the recess 21. A top surface of the encapsulation layer 40 is coplanar with a top surface of the reflector 20. The encapsulation body 40 is made of transparent material such as silicone. Furthermore, the encapsulation body 40 can be mixed with fluorescent particles whereby light generated by the LED die 30 can be mixed with light generated by the fluorescent particles to generate light having a desired color, which generally is white.

Due to the interlocked arrangement along a horizontal direction between the first extending portion 112 and the second extending portion 122, and the tortuous gap 50 between the first and second electrodes 11, 12, the reactive stress induced by mounting the side view LED package 100 to the printed circuit board can be effectively resisted not only by the substrate 60 but also by the electrode structure 10 which has a higher strength. Accordingly, the break of the LED package at the gap between the first electrode and the second electrode of the conventional art can be avoided by the LED package 100 in accordance with the present disclosure.

The disclosure provides a manufacturing method for the LED package 100 which includes the following steps.

The electrode structure 10 is provided. The electrode structure 10 includes the first electrode 11 and the second electrode 12.

The first electrode 11 and the second electrode 12 are arranged in an interlocked manner along a horizontal direction to form the tortuous gap 50 therebetween. Specifically, the first main body 111 and the free end of the second extending portion 122 are spaced to form the first extending section 51.

The second main body 121 and the free end of the first extending portion 112 are spaced to form a second extending section 52. The first extending portion 112 and the second extending portion 122 are spaced from each other whereby a middle section 53 is located between the first and second extending portions 112, 122. The middle section 53 is perpendicular to the first extending section 51 and the second extending section 52.

A mold (not shown) is provided, and the electrode structure 10 is put in a cavity of the mold. Resin materials are injected into the cavity to form the resin layer 17, the reflector 20 and the substrate 60 which are integrated as a single piece. Specifically, the resin materials filled in the first groove 15, the second groove 16 and peripheries of the second surfaces 14 of the first electrode 12 and the second electrode 12 form the resin layer 17. The resin materials filled in the gap 50 form the substrate 60. The resin materials filled over the first and second electrodes 11, 12 form the reflector 20, and the reflector 20 includes a recess 21 at a center thereof.

The mold is removed, and the LED die 30 is arranged on the electrode structure. Specifically, the LED die 30 is arranged on the second main body 121 and electrically connects with the first extending portion 112 and the second main body 121 by wire bonding.

The encapsulation layer 40 is formed in the recess 21 of the reflector 20 to cover the LED die 30. The top surface of the encapsulation layer 40 is coplanar with the top surface of the reflector 20.

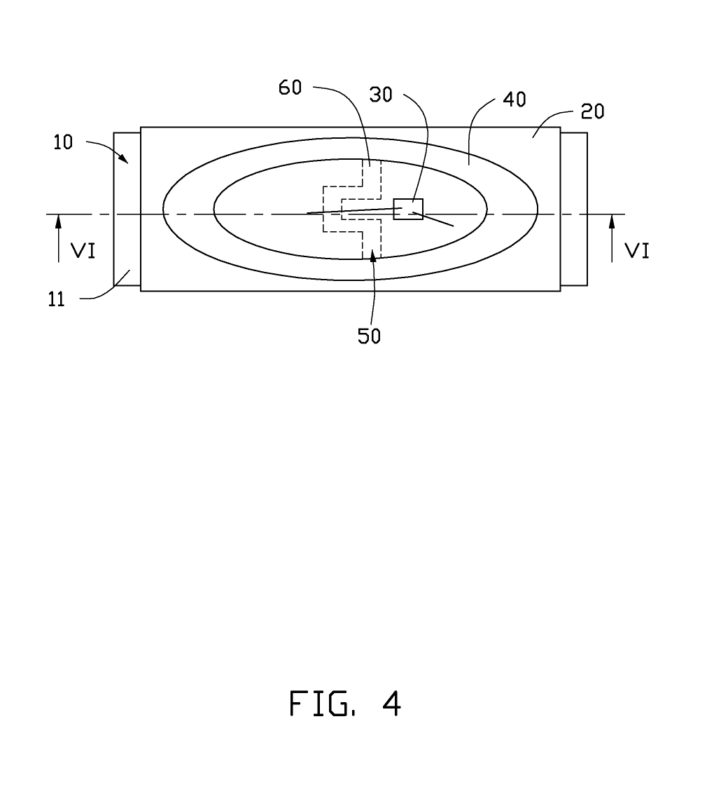

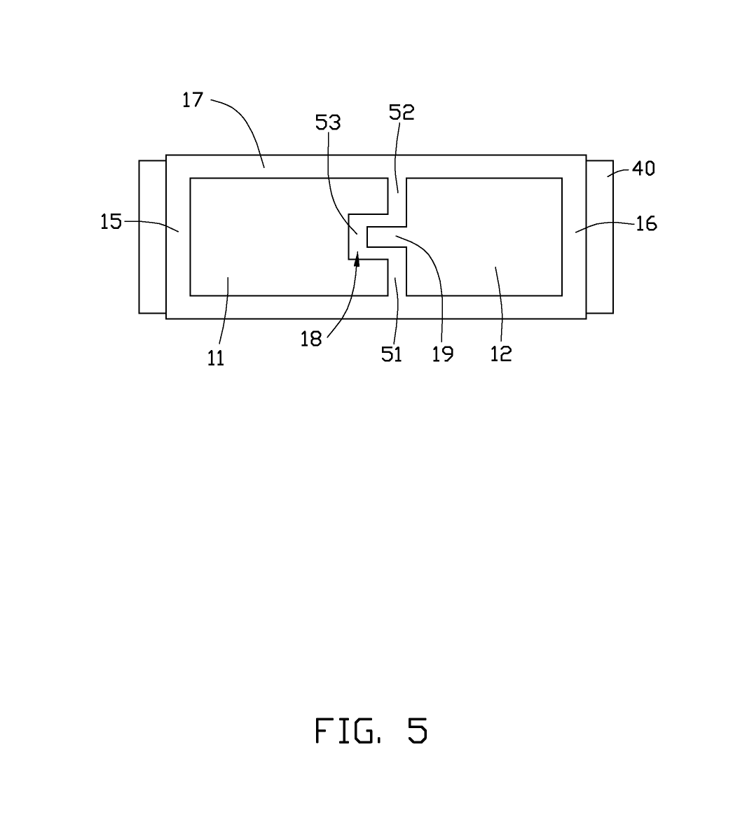

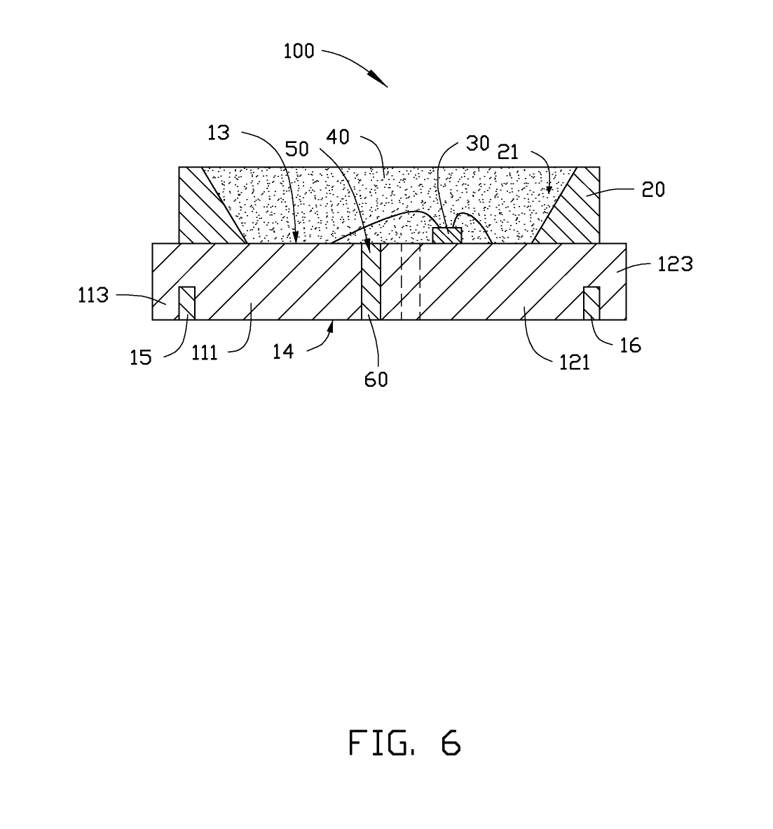

Referring to FIGS. 4 to 6, a side view LED package 200 in accordance with a second exemplary embodiment is provided. The side view LED package 200 is similar to the LED package 100. The difference is that the first electrode 11 includes a receiving portion 18 at one side thereof near to the second electrode 12 along a horizontal direction of the LED package 200, and the second electrode 12 includes a protruding portion 19 at one side near to the first electrode 11 along the horizontal direction of the LED package 200. A shape of the protruding portion 19 is matched with the receiving portion 18, while the protruding portion 19 has a smaller size. A free end of the protruding portion 19 is received in the receiving portion 18 and spaced from the first electrode 11 to form the gap 50 whereby the gap 50 is tortuous in configuration. In this embodiment, the receiving portion 18 is a square groove, and the protruding portion 19 is rectangular.

The gap 50 includes a first extending section 51, a second extending section 52, and a middle section 53 between the first extending section 51 and the second extending section 52. The middle section 53 is generally U-shaped which opens toward the second electrode 12. Specifically, the first and second extending sections 51, 52 are aligned with each other and separated by the protruding portion 19. Facing inner ends of the first and second extending sections 51, 52 respectively connect with bottom and top opening ends of the middle section 53. Accordingly, the gap 50 is tortuous and reactive stress induced by thermal stress caused by mounting the side view LED package 200 to a printed circuit board can resisted by not only the substrate 60 in the gap 50 by also the electrode structure around the gap 50. Accordingly, the possibility of break of the LED package 200 due to the thermal stress can be significantly reduced.

Alternatively, shapes of the receiving portion 18 and the protruding portion 19 may be other shape such as triangular, rhombus and so on.

It is to be understood that the above-described embodiments are intended to illustrate rather than limit the disclosure. Variations may be made to the embodiments without departing from the spirit of the disclosure. The above-described embodiments illustrate the scope of the disclosure but do not restrict the scope of the disclosure.

What is claimed is:

1. A side view light emitting diode (LED) package, comprising:
an electrode structure comprising a first electrode and a second electrode spaced from each other, a part of the first electrode extending thorough a border of the second electrode near the first electrode to reach an inside of the second electrode;
an LED die electrically connecting with the first electrode and the second electrode;
an encapsulation layer covering the LED die, the encapsulation layer comprising a light outputting surface;
a substrate interconnecting the first and second electrodes together;
wherein a gap between the first electrode and second electrode is filled by the substrate and the gap has a tortuous configuration.

2. The side view LED package of claim 1, wherein the gap comprises two extending sections and a middle section interconnecting the two extending sections, the middle section and each of the two extending sections being not parallel.

3. The side view LED package of claim 2, wherein the middle section is perpendicular to the two extending sections.

4. The side view LED package of claim 1, wherein the first electrode comprises a first main body, and a first extending portion extending toward the second electrode from one side of the first main body along a horizontal direction.

5. The side view LED package of claim 4, wherein the second electrode comprises a second main body, and a second extending portion extending toward the first electrode from one side of the second main body along a horizontal direction.

6. The side view LED package of claim 5, wherein the first extending portion and the second extending portion are arranged in an overlapped manner, and a surface of the first extending portion and a surface of the second extending portion are parallel with each other to define a middle section of the gap.

7. The side view LED package of claim 6, wherein the first electrode comprises a first soldering bump extending away from the second electrode, the second electrode comprising a second soldering bump extending away from the first electrode, a size of the first soldering bump being the same as that of the second soldering bump, the first soldering bump and the second soldering bump being symmetrically arranged at two sides of the LED package.

8. The side view LED package of claim 7, wherein a first groove is defined on an edge of a bottom surface of the first main body adjacent to the first soldering bump, a second groove being defined on an edge of a bottom surface of second main body, the first groove, the second groove and peripheries of the bottom surfaces of the first electrode and the second electrode being filled resin materials to form a resin layer which is integrated with the substrate as a single piece, a distance between each of side surfaces of the first soldering bump and the second soldering bump and a side surface of the side view LED package being smaller than 100 micrometers.

9. The side view LED package of claim 2, wherein the first electrode comprises a receiving portion formed at one side of the first electrode near the second electrode, the second electrode comprising a protruding portion corresponding to the receiving portion formed at one side of the second electrode near the first electrode, a shape of the receiving portion being matched with a size of the protruding portion, a free end of the protruding portion being extended into and received in the receiving portion and spaced from the receiving portion of the first electrode to form the middle section of the gap.

10. The side view LED package of claim 9, wherein the receiving portion and the protruding portion are spaced from each other to form the middle section, the middle portion being U-shaped.

11. A method for manufacturing a side view light emitting diode (LED) package comprising steps:
providing an electrode structure with a first electrode and a second electrode spaced from each other by a gap wherein the gap is tortuous, arranging the first electrode and the second electrode in an interlocked manner along a horizontal direction in a mold;
injecting resin material into the mold to fill the gap wherein the resin material interconnects the first and second electrodes together;
disposing an LED die on the electrode structure and electrically connecting the LED die with the first electrode and the second electrode; and
covering an encapsulation layer on the LED die, the encapsulation layer comprising a light outputting surface parallel to a horizontal direction.

12. The method for manufacturing a side view LED package of claim 11, wherein the injection of the resin material into the mold also forms a reflector on the electrode structure, wherein the reflector is integral with the resin material in the gap as a single piece.
